(19) United States
(12) Patent Application Publication
(10) Pub. No.: US 2026/0302968 A1
(43) Pub. Date: Oct. 1, 2026

(54) POWER SUPPLY INPUT CIRCUIT AND INVERTER-INTEGRATED VEHICULAR ELECTRIC COMPRESSOR EQUIPPED WITH SAME

(71) Applicant: SANDEN CORPORATION, Isesaki-shi, Gunma (JP)

(72) Inventors: Masatoshi SAITO, Isesaki-shi, Gunma (JP); Hiroshi YOSHIDA, Isesaki-shi, Gunma (JP)

(21) Appl. No.: 19/490,988

(22) PCT Filed: Aug. 7, 2024
(86) PCT No.: PCT/JP2024/028209

§ 371 Date: Dec. 8, 2025

(30) Foreign Application Priority Data
Sep. 14, 2023 (JP) 2023-149459

(51) Int. Cl. H02M 7/539; H02M 1/32

(52) U.S. Cl. CPC H02M 7/539; H02M 1/32

(57) ABSTRACT

Provided is a power input circuit capable of suppressing the fluctuation of an inrush current due to the influence of ambient temperature and shortening the rise time of a voltage supplied to a load. A power input circuit includes a current detection resistor (9) that detects a current with a voltage generated at both ends by an inrush current, and a current limiting switching element (Q3) of which a collector is connected to a gate of a power switching element (Q2). In the current limiting switching element (Q3), a voltage of a base changes in response to a voltage generated at both ends of the current detection resistor (9), a voltage of the gate of the power switching element (Q2) is adjusted to perform a constant current operation, and a negative temperature coefficient thermistor (17) is connected between the base and an emitter of the current limiting switching element (Q3).

### TECHNICAL FIELD

The present invention relates to a power input circuit from a DC power supply to a load, and a vehicle inverter-integrated electric compressor equipped with the power input circuit, the vehicle inverter-integrated electric compressor limiting an inrush current.

### BACKGROUND ART

For example, in an inverter-integrated electric compressor mounted on a vehicle, there is a risk that, in a low-voltage power supply input unit of a control circuit that controls an inverter, an inrush current rapidly flows when a low-voltage power supply (battery: DC power supply) is connected, and an element is damaged. Therefore, a power input circuit is designed. The power input circuit limits an inrush current using a power switching element, a current detection resistor, and a current limiting switching element, and performs a constant current operation so as not to carry an excessive inrush current (see, for example, Patent Literature 1).

### CITATION LIST

### Patent Literature

Patent Literature 1: JP 2019-205286 A

### SUMMARY OF INVENTION

### Problems to be Solved by Invention

The current limiting switching element includes, for example, a bipolar transistor or the like. However, its characteristics change due to ambient temperature conditions. Therefore, problems arise when the ambient temperature decreases, the inrush current exceeds a predetermined limit value, and conversely, when the ambient temperature increases, the rise time of the voltage (load-side voltage) supplied to the load delays.

Such a change in the current limit value poses a significant problem in a vehicle inverter-integrated electric compressor, which demands a wide operating temperature range.

The present invention has been made to solve the related-art technical problems, and an object of the present invention is to provide a power input circuit capable of suppressing fluctuation of an inrush current due to the influence of an ambient temperature and shortening a rise time of a voltage supplied to a load, and a vehicle inverter-integrated electric compressor equipped with the power input circuit.

### Solution to Problems

A power input circuit according to the present invention includes a power switching element connected between a DC power supply and a load, the power switching element changing a voltage of a control electrode of the power switching element to control a current from the DC power supply to the load. The power input circuit includes a current detection resistor of which the voltage is induced at both ends by an inrush current, and a current limiting switching element having a control electrode and a pair of main electrodes, one of the main electrodes being connected to the control electrode of the power switching element. In the current limiting switching element, the voltage of the control electrode of the current limiting switching element changes in response to the voltage induced at both ends of the current detection resistor, the voltage of the control electrode of the power switching element is adjusted to perform a constant current operation, and a negative temperature coefficient thermistor is connected between the control electrode of the current limiting switching element and the other main electrode.

In the above-described invention, in the power input circuit according to the invention of claim 2, the other main electrode of the current limiting switching element is connected to the other end of the current detection resistor, and a first resistor is connected between one end of the current detection resistor and the control electrode of the current limiting switching element, and the negative temperature coefficient thermistor is connected in parallel with a series circuit of the current detection resistor and the first resistor.

In the above-described invention, the power input circuit according to the invention of claim 3 includes a second resistor connected in series with the negative temperature coefficient thermistor between the control electrode of the current limiting switching element and the other main electrode, and a third resistor connected in parallel with a series circuit of the negative temperature coefficient thermistor and the second resistor between the control electrode of the current limiting switching element and the other main electrode.

In the invention of claim 1, in the power input circuit according to the invention of claim 4, the current detection resistor and the power switching element are provided on a positive-side power supply line of the DC power supply, one end of the current detection resistor is connected to one of the main electrodes of the power switching element, and a switch circuit is provided, which is connected between the control electrode of the power switching element and a negative-side power supply line of the DC power supply via a fourth resistor.

In the invention described above, the power input circuit according to the invention of claim 5 includes an input capacitor connected between a positive-side power supply line and a negative-side power supply line of the DC power supply on the other end side of the current detection resistor, and an output capacitor connected between the positive-side power supply line and the negative-side power supply line of the DC power supply on the other main electrode side of the power switching element.

In the invention of claim 1, in the power input circuit according to the invention of claim 6, the power switching element is a voltage-driven switching element having a gate as a control electrode, the current limiting switching element is a bipolar transistor having a base as a control electrode and a collector and an emitter as a pair of main electrodes, the collector of the bipolar transistor is connected to the gate of the power switching element, and the negative temperature coefficient thermistor is connected between the base and the emitter of the bipolar transistor.

A vehicle inverter-integrated electric compressor according to the invention of claim 7 includes the power input circuit of the above-described inventions and a control circuit that controls an inverter as a load.

### Effects of Invention

According to the present invention, in the power input circuit that includes the power switching element connected between the DC power supply and the load and controls a current from the DC power supply to the load by changing the voltage of the control electrode of the power switching element, the power input circuit includes the current detection resistor in which a voltage is induced at both ends by an inrush current, and the current limiting switching element that includes a control electrode and a pair of main electrodes and in which one main electrode is connected to the control electrode of the power switching element, a voltage of the control electrode of the current limiting switching element changes corresponding to a voltage induced at both ends of the current detection resistor, the current limiting switching element adjusts a voltage of the control electrode of the power switching element to perform a constant current operation, and the negative temperature coefficient thermistor is connected between the control electrode of the current limiting switching element and the other main electrode. Accordingly, the voltage across the control electrode and the other main electrode of the current limiting switching element, which varies depending on the ambient temperature, and the current flowing through the control electrode are compensated, the voltage across the current detection resistor is controlled, and thus, it is possible to limit the maximum current flowing across the main electrodes of the power switching element to a predetermined value.

As a result, it is possible to suppress the fluctuation of the inrush current due to the influence of the ambient temperature and eliminate the inconvenience of exceeding the predetermined limit value, and it is also possible to shorten the rise time of the voltage supplied to the load.

In addition, actually, as in the invention of claim 2, the other main electrode of the current limiting switching element is connected to the other end of the current detection resistor, and the first resistor is connected between the one end of the current detection resistor and the control electrode of the current limiting switching element, and thus, the negative temperature coefficient thermistor is connected in parallel with the series circuit of the current detection resistor and the first resistor. As a result, the current flowing through the first resistor connected to the control electrode of the current limiting switching element is compensated by the negative temperature coefficient thermistor.

In addition, as in the invention of claim 3, when the second resistor serially connected to the negative temperature coefficient thermistor is provided between the control electrode of the current limiting switching element and the other main electrode and the third resistor connected in parallel with the negative temperature coefficient thermistor and the series circuit of the second resistor is provided between the control electrode of the current limiting switching element and the other main electrode, it is possible to set the maximum current and the minimum current flowing through the first resistor, and the degree of freedom of the temperature compensation characteristic by the negative temperature coefficient thermistor is improved.

Specifically, as in the invention of claim 4, the current detection resistor and the power switching element are provided in the positive-side power supply line of the DC power supply, one end of the current detection resistor is connected to one main electrode of the power switching element, and the switch circuit is connected between the control electrode of the power switching element and the negative-side power supply line of the DC power supply via the fourth resistor.

In addition, as in the invention of claim 5, the input capacitor is connected between the positive-side power supply line and the negative-side power supply line of the DC power supply on the other end side of the current detection resistor, and the output capacitor is connected between the positive-side power supply line and the negative-side power supply line of the DC power supply on the other main electrode side of the power switching element.

Further, as in the invention of claim 6, the power switching element is constituted of the voltage-driven switching element having a gate as the control electrode, the current limiting switching element is constituted of the bipolar transistor having a base as the control electrode and a collector and an emitter as a pair of main electrodes, the collector of the bipolar transistor is connected to the gate of the power switching element, and the negative temperature coefficient thermistor is connected between the base and the emitter of the bipolar transistor.

Unlike home electric appliances and the like, the power input circuit described above is extremely suitable in the case in which a control circuit that controls an inverter is applied as a load in the vehicle inverter-integrated electric compressor according to the invention of claim 7 in which a wide operating temperature range is demanded.

### BRIEF DESCRIPTION OF DRAWINGS

FIG. 1 is an electric circuit diagram of a power input circuit according to an embodiment, to which the present invention is applied (Example 1).

FIG. 2 is a diagram that explains the temperature characteristics of an inrush current and a load-side voltage of the power input circuit of FIG. 1 in comparison with the related art.

FIG. 3 is an electric circuit diagram of a power input circuit of another embodiment, to which the present invention is applied (Example 2).

FIG. 4 is an electric circuit diagram of a related-art power input circuit without a negative temperature coefficient thermistor.

### DESCRIPTION OF EMBODIMENTS

Hereinafter, an embodiment of the present invention will be described in detail with reference to the drawings.

### Example 1

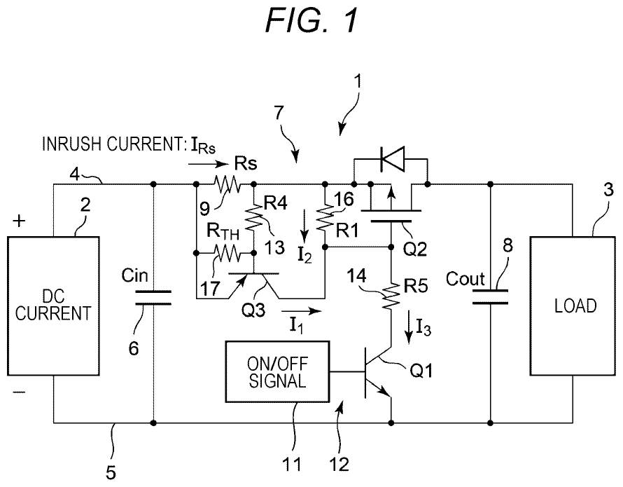

FIG. 1 shows an electric circuit diagram of a power input circuit 1 according to an example, to which the present invention is applied. In this diagram, a power input circuit 1 of the example supplies a DC voltage from a DC power supply 2 including a battery (e.g., a low-voltage power supply of 12 DC V) mounted on a vehicle to a load 3 such as a DC/DC converter constituting a control circuit of a vehicle inverter-integrated electric compressor (not shown) also mounted on the vehicle, and includes an input capacitor 6 having a capacitance value Cin, an inrush current limiting circuit 7, and an output capacitor 8 having a capacitance value Cout, all of which are connected between a positive-side power supply line 4 (+) and a negative-side power supply line 5 (−) of the DC power supply 2.

In this case, the input capacitor 6 is connected between the positive-side power supply line 4 and the negative-side power supply line 5 on the DC power supply 2 side (the other end side of a current detection resistor 9, described later) of the inrush current limiting circuit 7, and the output capacitor 8 is connected in parallel with the load 3 between the positive-side power supply line 4 and the negative-side power supply line 5 on the load 3 side (the other main electrode side of a power switching element Q2, described later) of the inrush current limiting circuit 7.

The inrush current limiting circuit 7 to which the present invention is applied includes the current detection resistor 9 described above having a resistance value Rs, a switch circuit 12 including a switching element Q1 configured by an NPN type transistor (bipolar transistor) and an ON/OFF signal circuit 11 in the example, the power switching element Q2 described above including a P type MOS-FET as an example of a voltage-driven switching element, a current limiting switching element Q3 configured by a PNP type transistor (bipolar transistor) in the example, a first resistor 13 having a resistance value R4, a fourth resistor 14 having a resistance value R5, a fifth resistor 16 having a resistance value R1, and a negative temperature coefficient thermistor 17 of which a resistance value R_{TH} changes with ambient temperature.

The current detection resistor 9 and the power switching element Q2 are connected in series to the positive-side power supply line 4 between the DC power supply 2 and the load 3. In this case, the other end of the current detection resistor 9 is connected to the end portion of the input capacitor 6 on the positive-side power supply line 4 side, one end of the current detection resistor 9 is connected in series to the source as one main electrode of the power switching element Q2, and the drain as the other main electrode of the power switching element Q2 is connected to the end portion of the output capacitor 8 on the positive-side power supply line 4 side.

In addition, one end of the fourth resistor 14 is connected to a gate as the control electrode of the power switching element Q2, and a collector as one main electrode of the switching element Q1 is connected to the other end of the fourth resistor 14. The emitter as the other main electrode of the switching element Q1, is connected to the negative-side power supply line 5, and thus, the switch circuit 12 is connected between the gate of the power switching element Q2 and the negative-side power supply line 5 via the fourth resistor 14. The output of the ON/OFF signal circuit 12 is connected to a base as the control electrode of the switching element Q1.

In addition, the collector as one main electrode of the current limiting switching element Q3 is connected to the gate of the power switching element Q2, and the emitter as the other main electrode of the current limiting switching element Q3 is connected to the positive-side power supply line 4 at the other end of the current detection resistor 9. The fifth resistor 16 is connected between the source and the gate of the power switching element Q2, and the first resistor 13 is connected between the positive-side power supply line 4 at one end of the current detection resistor 9 and the base as the control electrode of the current limiting switching element Q3. The negative temperature coefficient thermistor 17 is connected between the base and the emitter of the current limiting switching element Q3, and thus, the negative temperature coefficient thermistor 17 is connected in parallel with the series circuit of the current detection resistor 9 and the first resistor 14.

### (1) Constant Current Operation

Next, the operation of the power input circuit 1 of FIG. 1 will be described. When power is supplied from the DC power supply 2 to the load 3 at the time of starting the electric compressor described above, the signal output from the ON/OFF signal circuit 11 of the switch circuit 12 changes from OFF to ON. By this ON signal output, the switching element Q1 (NPN bipolar transistor) is turned on. When the switching element Q1 is turned on, since the collector of the switching element Q1 is connected to the gate of the power switching element Q2 via the fourth resistor 14, a voltage is applied to the gate of the power switching element Q2, and the power switching element Q2 is turned on.

The turning on of the power switching element Q2 causes a rapid flow of a charging current (inrush current I_{Rs}) from the DC power supply 2 to the output capacitor 8, through the current detection resistor 9, the source and the drain of the power switching element Q2. The current detection resistor 9 is connected in series to the source of the power switching element Q2, and the voltage induced across the current detection resistor 9 increases in response to the value of the inrush current I_{Rs}. As a result, the base bias voltage of the current limiting switching element Q3 increases to turn ON, and a current (collector current) I₁ flows from the emitter to the collector.

Since the collector current I₁ of the current limiting switching element Q3 flows to the collector of the switching element Q1 via the fourth resistor 14, as a result, the voltage applied to the gate of the power switching element Q2 is controlled (adjusted) in a limited direction, and the charging current (inrush current I_{Rs}) of the output capacitor 8 flowing from the source through the drain is limited. That is, a constant current operation is performed in which the current flowing through the current detection resistor 9 does not exceed a predetermined value, and the drain current (inrush current I_{Rs}) of the power switching element Q2 is limited.

In this manner, the current limiting switching element Q3 causes the power switching element Q2 to perform the constant current operation to set the resistance value Rs of the current detection resistor 9 and the resistance value R4 of the first resistor 13 connected to the current limiting switching element Q3, and thus, the maximum current (the maximum value of the inrush current I_{Rs}) flowing between the source and the drain of the power switching element Q2 can be limited to a predetermined value. After charging of the output capacitor 8 is completed, the DC voltage is then stably supplied from the DC power supply 2 to the load 3.

### (2) Operation of Negative Temperature Coefficient Thermistor 17

Next, the operation of the negative temperature coefficient thermistor 17 of the power input circuit 1 (FIG. 1) of the present invention will be described using a formula while being compared with the related-art power input circuit 100 (FIG. 4) without the negative temperature coefficient thermistor 17. Note that in FIG. 4, components denoted by the same reference numerals as those in FIG. 1 are assumed to exert the same or similar operations. However, resistance values Rs, R4, R5, and R1 of resistors 9, 13, 14, and 16 constituting an inrush current limiting circuit 101 in FIG. 4 are different from those in FIG. 1 as described later, and since the negative temperature coefficient thermistor 17 in FIG. 1 is not provided, the inrush current limiting circuit is also indicated by another reference numeral 101.

In the case of FIG. 1, the inrush current I_{Rs} (charging current of the output capacitor 8) is expressed by formula (I) below. Here, Rs represents the resistance value of the current detection resistor 9, and V_{BE} represents the base-emitter voltage of the current limiting switching element Q3. The current limiting switching element Q3 is a PNP transistor (bipolar transistor), and since the voltage V_{BE} is a negative value, −V_{BE} is a positive value. In addition, V_{R4} is an end-to-end voltage across the first resistor 13, and is expressed by formula (II). Note that R4 is the resistance value of the first resistor 13, and R_{TH} is the resistance value of the negative temperature coefficient thermistor 17.

$$\begin{matrix}[ Formula 1 ] & \\ {I}_{Rs} = \frac{- {V}_{BE} + {V}_{R 4}}{Rs} & ( I )\end{matrix}$$

$${V}_{R 4} = R 4 \times ( {I}_{b} + \frac{- {V}_{BE}}{{R}_{TH}} ) \qquad ( II )$$

I_{b} in formula (II) is a base current of the current limiting switching element Q3 and is expressed by formula (III) below. Note that hFE in formula (III) is a current amplification factor of the current limiting switching element Q3. In addition, I_{c} is a collector current and is the same as I₁ (formula (IV) below). The current I₁ is a value obtained by subtracting the current I₂ flowing through the fifth resistor 16 from the collector-emitter current I₃ of the switching element Q1 (the following formula (V)), and the current I₃ is expressed by formula (VI) below.

In addition, in formula (VI), VDC is the voltage of the DC power supply 2, V_{GS} is the gate-source voltage of the power switching element Q2, V_{CE} is the collector-emitter voltage of the switching element Q1, R5 is the resistance value of the fourth resistor 14, and I_{Rs} is repeatedly calculated. In addition, the current I₂ is expressed by formula (VII) below. In formulas (VI) and (VII), the gate-source voltage Vos of the power switching element Q2 is multiplied by minus because the power switching element Q2 includes a P-type MOS-FET.

$$\begin{matrix}[ Formula 2 ] & \\ {I}_{b} = \frac{{I}_{c}}{hFE} & ( III )\end{matrix}$$

$${I}_{c} = {I}_{1} \qquad ( IV )$$

$${I}_{1} = {I}_{3} - {I}_{2} \qquad ( V )$$

$${I}_{3} = \frac{{V}_{DC} - {I}_{Rs} \times Rs - ( - {V}_{GS} ) - {V}_{CE}}{R 5} \qquad ( VI )$$

$${I}_{2} = \frac{- {V}_{GS}}{R 1} \qquad ( VII )$$

The numerator of formula (I) above is obtained by adding an end-to-end voltage V_{R4} of the first resistor 13 to a value −V_{BE} obtained by multiplying the base-emitter voltage V_{BE} of the current limiting switching element Q3 by minus, which is the end-to-end voltage of the current detection resistor 9. Formula (I) means that a value obtained by dividing the end-to-end voltage by the resistance value Rs of the current detection resistor 9 (denominator of formula (I)) is the inrush current I_{Rs}.

In addition, the parenthesis on the right side of formula (II) above indicates the current flowing through the first resistor 13 in the case of this example, and formula (II) means that the current multiplied by the resistance value R4 is the end-to-end voltage V_{R4} of the first resistor 13. The second term (right side) in parentheses on the right side of formula (II) is the temperature compensation term by the negative temperature coefficient thermistor 17.

The reason will be described. As described above, the current limiting switching element Q3, including the bipolar transistor, has a temperature characteristic, and the voltage V_{BE} has a negative characteristic in which the voltage decreases as the ambient temperature increases. That is, when the ambient temperature decreases, the voltage V_{BE} has a negative value and an absolute value increases, and −V_{BE} in formula (I) has a positive value and an absolute value increases. Conversely, when the ambient temperature increases, the voltage V_{BE} takes on a negative value, and its absolute value decreases, and −V_{BE} in formula (I) becomes positive and also decreases.

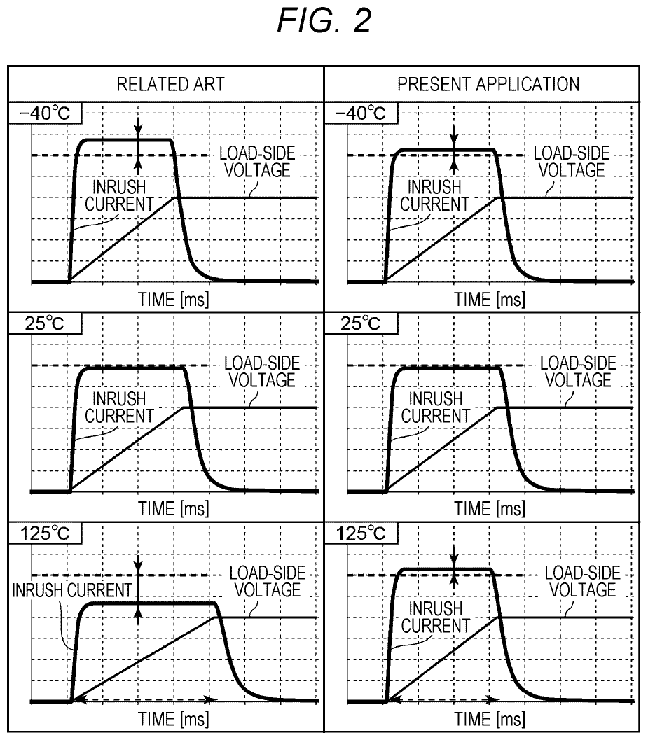

Therefore, in the case of the power input circuit 100 (related art) of FIG. 4 (there is no second term in parentheses of formula (II)), for example, at −40° C. where the ambient temperature is low, the numerator on the right side of formula (I) becomes large, and as shown in the upper left part of FIG. 2, the maximum value of the inrush current I_{Rs} becomes higher than that at the standard temperature shown in the middle part, for example, +25° C. (the maximum value is shown by a broken line in FIG. 2). Conversely, for example, at +125° C. where the ambient temperature is high, the numerator of formula (I) becomes small, and thus, the inrush current I_{Rs} becomes low as shown in the lower part.

That is, in the related-art power input circuit 100 without the negative temperature coefficient thermistor 17, even though the value of each element (the resistance value of each resistor or the like) is set so as not to exceed the limit value at the standard temperature (+25° C.), there is a problem that an excessive inrush current I_{Rs} larger than the maximum value in the case of the standard temperature flows under a condition where the ambient temperature is low (−40° C.).

On the other hand, in the power input circuit 1 of the present invention shown in FIG. 1, since the negative temperature coefficient thermistor 17 is connected between the base and the emitter of the current limiting switching element Q2, the second term in parentheses is included as in formula (II) described above. Since the negative temperature coefficient thermistor 17 has a characteristic that the resistance value R_{TH} increases as the temperature decreases and the resistance value R_{TH} decreases as the temperature increases, the second term in parentheses on the right side of formula (II) decreases, and the end-to-end voltage V_{R4} of the first resistor 13 decreases as the ambient temperature decreases. Conversely, when the ambient temperature increases, the second term in parentheses on the right side of formula (II) increases, and the voltage V_{R4} increases.

As a result, although-V_{BE} on the right side of formula (I) increases as a positive value as the ambient temperature decreases, V_{R4} conversely decreases, and thus, the increase in the inrush current I_{Rs} due to the increase in-V_{BE} is suppressed by the decrease in V_{R4}. That is, the negative temperature coefficient thermistor 17 compensates the base-emitter voltage V_{BE} of the current limiting switching element Q3 and the base current I_{b} of the current limiting switching element Q3 in formula (II) varying depending on the ambient temperature, and controls the voltage across the current detection resistor 9, and the maximum value of the inrush current I_{Rs} flowing between the source and the drain of the power switching element Q2 is limited to a predetermined value (suppressed within a predetermined limit value).

This state is shown on the right side of FIG. 2. Similarly to the left side (related art), the middle part shows the maximum value of the inrush current I_{Rs} at the standard temperature +25° C. and the broken line shows the maximum value of the inrush current I_{Rs} at the temperature +25° C. It can be seen that due to the temperature compensation effect by the negative temperature coefficient thermistor 17 as described above, even in the case of a low ambient temperature of −40° C., the maximum value of the inrush current I_{Rs} is suppressed to substantially the same value as that at the middle standard temperature +25° C. (broken line).

Note that the resistance values Rs, R4, R5, and R1 of the resistors 9, 14, 13, and 16 are set such that the maximum value (broken line) of the inrush current I_{Rs} is the same on the left side (the circuit without the related-art negative temperature coefficient thermistor 17) and the right side (the present invention) in FIG. 2 in the case of the standard temperature +25° C. That is, each resistance value is set differently between the case of FIG. 1 and the case of FIG. 4.

On the other hand, since the resistance value R_{TH} of the negative temperature coefficient thermistor 17 decreases as the ambient temperature increases, the second term in parentheses on the right side of formula (II) increases as the ambient temperature increases. As a result, since the voltage V_{R4} increases, −V_{BE} on the right side of formula (I) decreases as a positive value as the ambient temperature increases. However, V_{R4} conversely increases, and the decrease in the inrush current I_{Rs} caused by the decrease in −V_{BE} due to the similar temperature compensation effect is suppressed by the increase in V_{R4}.

This state is shown in the lower right part of FIG. 2. Due to the temperature compensation effect of the negative temperature coefficient thermistor 17 as described above, when the ambient temperature is high at +125° C., the maximum value of the inrush current I_{Rs} is maintained substantially equal to that in the case of the intermediate standard temperature +25° C. (broken line). As a result, since the charging current to the output capacitor 8 also increases in the related-art circuit of FIG. 4, the rise time of the load-side voltage (the charging voltage of the output capacitor 8) becomes shorter as indicated by the dashed double-headed arrow in FIG. 2 as compared with the related-art circuit (the lower left part of FIG. 2).

As described above, according to the present invention, since the negative temperature coefficient thermistor 17 is connected between the base and the emitter of the current limiting switching element Q3, it is possible to limit the maximum value (maximum current) of the inrush current I_{Rs} flowing between the source and the drain of the power switching element Q2 to a predetermined value by compensating the base-emitter voltage V_{BE} of the current limiting switching element Q3 varying depending on the ambient temperature and the base current I_{b} and controlling the voltage across the current detection resistor 9.

As a result, it is possible to suppress the fluctuation of the inrush current I_{Rs} due to the influence of the ambient temperature and it is possible to eliminate the inconvenience of exceeding the predetermined limit value. In addition, as described above, it is also possible to shorten the rise time of the voltage (load-side voltage) supplied to the load 3.

### Example 2

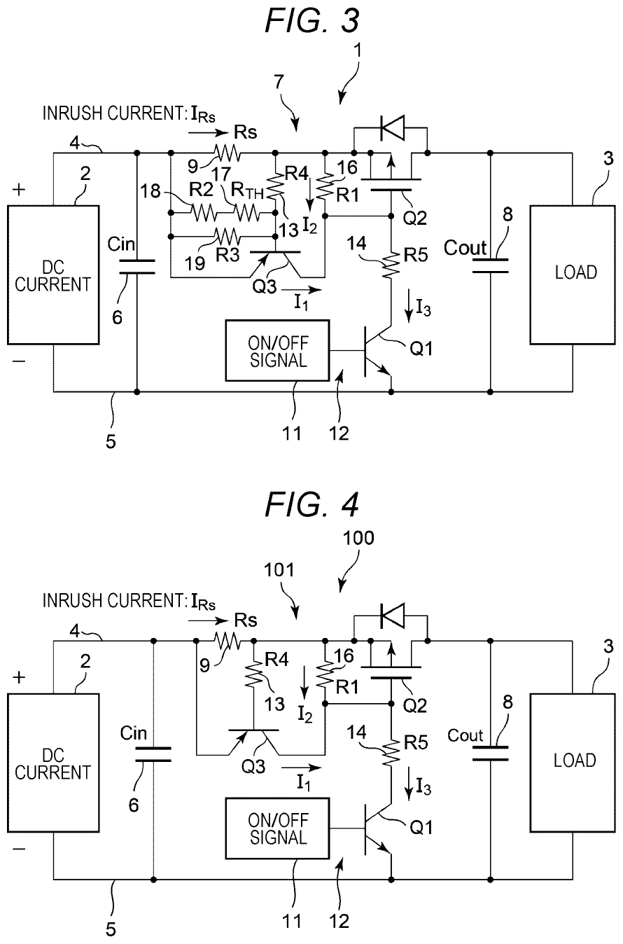

Next, FIG. 3 shows an electric circuit of another example of the power input circuit 1 of the present invention. Note that in this drawing, components denoted by the same reference numerals as those in FIG. 1 are assumed to exert the same or similar functions. In this example, a second resistor 18 having a resistance value R2 is connected in series with a negative temperature coefficient thermistor 17 between the base and the emitter of a current limiting switching element Q3, and a third resistor having a resistance value R3 is connected in parallel with the series circuit of the negative temperature coefficient thermistor 17 and a second resistor 18 between the base and the emitter of the current limiting switching element Q3.

An end-to-end voltage V_{R4} of a first resistor 13 in the case of the example is expressed by formula (VIII) below. Note that the formulas of the other parameters are similar to formulas (I), (III) to (VII) described above, also in the case of this example.

$$\begin{matrix}[ Formula 3 ] & \\ {V}_{R 4} = R 4 \times ( {I}_{b} + \frac{- {V}_{BE}}{R 3} + \frac{- {V}_{BE}}{R 2 + {R}_{TH}} ) & ( VIII )\end{matrix}$$

Also in the case of this example, the parenthesis on the right side of formula (VIII) indicates the current flowing through the first resistor 13, and formula (VIII) means that the current multiplied by the resistance value R4 is the end-to-end voltage V_{R4} of the first resistor 13. The third term (right end) in parentheses on the right side of formula (VIII) becomes a temperature compensation term by the negative temperature coefficient thermistor 17.

As described above, since the negative temperature coefficient thermistor 17 has a characteristic that the resistance value R_{TH} increases as the temperature decreases and the resistance value R_{TH} decreases as the temperature increases, the resistance value R3 of the third resistor 13 becomes dominant with respect to the current flowing through the first resistor 13 as the ambient temperature decreases in parentheses on the right side of formula (VIII), i.e., the third term of the current flowing through a first resistor 19. That is, the minimum value (minimum current) of the current flowing through the first resistor 13 is determined by the third resistor 19.

On the other hand, when the ambient temperature increases, R_{TH} in the denominator of the third term in the parentheses on the right side of formula (VIII) (the current flowing through the first resistor 13) decreases, and thus, the resistance value R2 of the second resistor 18 is dominant with respect to the current flowing through the first resistor 13. That is, the maximum value (maximum current) of the current flowing through the first resistor 13 is determined by the second resistor 18.

As in this example, when the second resistor 18 is connected in series with the negative temperature coefficient thermistor 17 between the base and the emitter of the current limiting switching element Q3 and the third resistor 19 is connected in parallel with the series circuit of the negative temperature coefficient thermistor 17 and the second resistor 18 between the base and the emitter of the current limiting switching element Q3, the maximum current and the minimum current flowing through the first resistor 13 can be set by the third resistor 19 and the second resistor 18, and the maximum value and the minimum value of the temperature compensation effect by the negative temperature coefficient thermistor 17 can be set to improve the degree of freedom of the temperature compensation characteristic by the negative temperature coefficient thermistor 17.

Note that in the examples, the DC/DC converter constituting the control circuit of the vehicle inverter-integrated electric compressor has been described as an example of the load. However, in the invention other than claim 7, the present invention is effective to control the current from the DC power supply to the load in general.

In addition, in the examples, the P-type MOS-FET is adopted as the power switching element Q2. However, the polarities of the power switching element Q2 and the switching elements Q1 (NPN type) and Q3 (PNP type) are not limited to the examples, and in the invention other than claims 4 and 5, for example, it is feasible by using an element having an opposite polarity as the negative-side power supply line 5 at the connection point.

### LIST OF REFERENCE SIGNS

1 Power input circuit
2 DC power supply
3 Load
4 Positive-side power supply line
5 Negative-side power supply line
6 Input capacitor
7 Inrush current limiting circuit
8 Output capacitor
9 Current detection resistor
12 Switch circuit
13 First resistor
14 Fourth resistor
16 Fifth resistor
17 Negative temperature coefficient thermistor
18 Second resistor
19 Third resistor
Q1 Switching element
Q2 Power switching element
Q3 Current limiting switching element

1. A power input circuit that includes a power switching element connected between a DC power supply and a load and that controls a current from the DC power supply to the load by changing a voltage of a control electrode of the power switching element, the power input circuit comprising:
a current detection resistor in which a voltage is induced at both ends by an inrush current; and
a current limiting switching element having a control electrode and a pair of main electrodes, one main electrode being connected to the control electrode of the power switching element, wherein
in the current limiting switching element, a voltage of the control electrode of the current limiting switching element changes in response to a voltage induced across the current detection resistor, the voltage of the control electrode of the power switching element is adjusted to perform a constant current operation, and
a negative temperature coefficient thermistor is connected between the control electrode and the other main electrode of the current limiting switching element.

2. The power input circuit according to claim 1, wherein the other main electrode of the current limiting switching element is connected to the other end of the current detection resistor, and a first resistor is connected between one end of the current detection resistor and the control electrode of the current limiting switching element, so that the negative temperature coefficient thermistor is connected in parallel with a series circuit of the current detection resistor and the first resistor.

3. The power input circuit according to claim 2, comprising:
a second resistor connected in series with the negative temperature coefficient thermistor between the control electrode and the other main electrode of the current limiting switching element; and
a third resistor connected in parallel with a series circuit of the negative temperature coefficient thermistor and the second resistor between the control electrode and the other main electrode of the current limiting switching element.

4. The power input circuit according to claim 1, wherein
the current detection resistor and the power switching element are provided in a positive-side power supply line of the DC power supply, and one end of the current detection resistor is connected to one main electrode of the power switching element, and
a switch circuit is provided, which is connected via a fourth resistor between the control electrode of the power switching element and a negative-side power supply line of the DC power supply.

5. The power input circuit according to claim 4, comprising:
an input capacitor connected between a positive-side power supply line and a negative-side power supply line of the DC power supply on the other end side of the current detection resistor; and
an output capacitor connected between the positive-side power supply line and the negative-side power supply line of the DC power supply on the other main electrode side of the power switching element.

6. The power input circuit according to claim 1, wherein
the power switching element is a voltage-driven switching element having a gate as the control electrode,
the current limiting switching element is a bipolar transistor including a base as the control electrode and a collector and an emitter as the pair of main electrodes, and
the collector of the bipolar transistor is connected to the gate of the power switching element, and the negative temperature coefficient thermistor is connected between the base and the emitter of the bipolar transistor.

7. A vehicle inverter-integrated electric compressor comprising:
the power input circuit according to claim 1; and
a control circuit that controls an inverter as the load.

8. A vehicle inverter-integrated electric compressor comprising:
the power input circuit according to claim 2; and
a control circuit that controls an inverter as the load.

9. A vehicle inverter-integrated electric compressor comprising:
the power input circuit according to claim 3; and
a control circuit that controls an inverter as the load.

10. A vehicle inverter-integrated electric compressor comprising:
the power input circuit according to claim 4; and
a control circuit that controls an inverter as the load.

11. A vehicle inverter-integrated electric compressor comprising:
the power input circuit according to claim 5; and
a control circuit that controls an inverter as the load.

12. A vehicle inverter-integrated electric compressor comprising:
the power input circuit according to claim 6; and
a control circuit that controls an inverter as the load.
